(19) United States
(12) Patent Application Publication
(10) Pub. No.: US 2026/0353682 A1
(43) Pub. Date: Nov. 5, 2026

(54) Semiconductor Capacitor Structures and Methods of Forming the Same

(71) Applicant: Taiwan Semiconductor Manufacturing Company, LTD., Hsinchu (TW)

(72) Inventors: Chun-Tsung Kuo, Tainan (TW); Hung-Wen Hsu, Tainan (TW); Jiech-Fun Lu, Madou (TW); Meng-Hsien Lin, Tainan (TW)

(21) Appl. No.: 19/198,023

(22) Filed: May 3, 2025

(51) Int. Cl. H10D 1/68; H10D 1/00

(52) U.S. Cl. CPC H10D 1/714; H10D 1/042; H10D 1/716

(57) ABSTRACT

A tube-in-tube capacitor structure, and method of forming the same, including an outer continuous conductive layer and an inner continuous conductive layer within an outer conductor inner region, the inner continuous conductive layer spaced apart from the outer continuous conductive layer sidewall to form a first dielectric gap region, and the inner continuous conductive layer formed to define a cylindrical shaped inner conductor inner region encircled by the inner continuous conductive layer sidewalls to provide a second dielectric gap region. A capacitor filler dielectric layer lines the first dielectric gap region and the second dielectric gap region, and a top metal conductive layer covers the capacitor filler dielectric layer within the first and second dielectric gap regions to provide a capacitor top electrode connection.

### BACKGROUND

The following relates to semiconductor integrated circuits (ICs) employing capacitive devices and/or structures, and to the manufacturing thereof.

Modem day integrated chips comprise millions or billions of semiconductor devices formed on a semiconductor substrate (e.g., silicon). Integrated chips (ICs) may use many different types of semiconductor devices, depending on an application of an IC, including, but not limited to, transistors, resistors, and/or capacitors, which may be interconnected through an interconnect layer to additional integrated circuits.

The evolution of ICs has led to an increase in functional density and a decrease in geometrical size associated with the semiconductor wafer and/or die layout of semiconductor devices, such as transistors, resistors, and/or capacitors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 1C and 1D are views of a metal-insulator-metal (MIM) capacitor structure including six capacitor bottom conductor sidewalls according to an example embodiment of this disclosure, the MIM capacitor structure (Embodiment 1) including one or more etched cavities formed within a dielectric region or substrate, where the MIM capacitor structure is formed within the cavities using a tube-in-tube conductor structure including a plurality of gap regions between the tubes for the deposition of a capacitor dielectric material and capacitor top metal layer. FIG. 1A shows a cross sectional view of Embodiment 1, FIG. 1B shows a perspective view of a tube-in-tube conductor structure, FIG. 1C shows another detail cross sectional view of an example tube-in-tube capacitor structure, and FIG. 1D shows a top view of an IC/substrate including a plurality of vias associated with an incomplete semiconductor die/substrate which are etched and enlarged to accommodate a MIM capacitor structure according to an example embodiment of this disclosure.

FIGS. 2A, 2B and 2C are views of a MIM capacitor structure including ten capacitor bottom conductor sidewalls according to an example embodiment of this disclosure, the MIM capacitor structure (Embodiment 2) including one or more etched cavities formed within a dielectric region or substrate, where the MIM capacitor structure is formed within the cavities using a tube-in-tube conductor structure including a plurality of gap regions between the tubes for the deposition of a dielectric material and capacitor top metal layer. FIG. 2A shows a cross sectional view of Embodiment 2, FIG. 2B shows a perspective view of a tube-in-tube conductor structure, and FIG. 2C shows another detail cross sectional view of an example tube-in-tube capacitor structure.

FIGS. 3A, 3B, 3C, 3D, 3E, 3F, 3G, 3H, 3I, 3J, 3K, 3L and 3M show a series of processes stages to manufacture/fabricate a MIM capacitor structure (Embodiment 3) according to an example embodiment of this disclosure, the process stages applicable to Embodiment 1, Embodiment 2 and other semiconductor structure/devices including a tube-in-tube capacitor structure having two or more conductors with at least one inner conductor tube encircled by at least one outer conductor tube.

FIG. 4 is a flow chart of a method of forming a capacitor structure according to an example embodiment of this disclosure, the capacitor structure formed with two or more continuous conductive layers to provide a tube-in-tube capacitor structure.

FIG. 5 is a flow chart of another method of forming a capacitor structure according to an example embodiment of this disclosure, the capacitor structure formed with two or more continuous conductive layers to provide a tube-in-tube capacitor structure.

FIGS. 6A and 6B, in combination, is a flow chart of another method of forming a capacitor structure according to an example embodiment of this disclosure, the capacitor structure formed by depositing an oxide layer on a first/outer continuous conductive layer prior to forming the second/inner continuous conductive layer, removing the oxide layer after forming the second/inner continuous conductive layer, and depositing a capacitive dielectric material, e.g. high-k (HK) dielectric material, within a gap region resulting from the removal of the oxide layer.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g., “about 2 to about 4” also discloses the range “from 2 to 4.” The term “about” may refer to plus or minus 10% of the indicated number.

The term “substrate” herein generally refers to the bulk substrate on which various layers and device structures are formed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “orthogonal axis,” as used herein, refers to an axis substantially at 90 degrees relative to a longitudinal axis of a structure.

The term “layer,” as used herein, may include a single layers or multiple layers.

The term “conductive feature,” as may be used herein refers to a metallization layer contact, patterned metallization layer contact, or other electrical metal contact.

The term “intermetal dielectric” (IMD) film or layer, as may be used herein, refers to a dielectric/insulation material(s) layer between two metal layers.

The term “interlayer dielectric” (ILD) layer, as may be used herein, refers to an insulating structure of material(s) placed between two conductive layers.

The term “line” and “metal line,” as may be used herein, is a conductive path that is created during the back end of line (BEOL) process and transmits electrical signals through a semiconductor chip's circuit pattern.

The term “stacked”, “vertically stacked”, “multilayer film stacking” and “multilayer layer stacking”, as used herein, refers to the stacking, layering or forming of a two or more capacitor MIM films or layers substantially arranged or formed in a layered pattern extending towards a cavity opening of a hole, e.g. etched or widened via, of which the MIM layers are deposited. The term “vertical” or “vertically” is not relative to gravity and can include a lateral layout where a first capacitor MIM conductor layer is laterally stacked and formed adjacent and offset to a second capacitor MIM conductor layer with structures as disclosed herein.

The term “tube-in-tube”, as used herein, refers to a conductor tube-in-tube arrangement where, for example, an inner tubular shaped capacitor conductor is encircled by an outer tubular shaped capacitor, with a gap region is located between the inner tubular shaped capacitor conductor and outer tubular shaped capacitor. The term “tube-in-tube”, as used herein, can also refers to a conductor “cylinder-in-cylinder”, and/or “conductor “cavity-in-cavity” arrangement. It is to be understood that the tube-in-tube arrangement is not limited to a single inner tubular shaped capacitor conductor and single outer tubular shaped capacitor conductor, and may include a plurality of tubular shaped capacitor conductors nested within each other to provide gap regions located between adjacent tubular shaped capacitor conductors.

The term “tube shaped”, “tubular shaped”, as used herein includes an elongated structure with sidewall(s) defining an inner region void of the material used to form the sidewalls. Examples of shapes which are defined as “tube shaped”, and “tubular shaped, include but are not limited to, cylindrical, elliptical, triangular, quadrilateral, hexagonal, oval, circular shaped sidewall, polygonal shaped sidewall, ring shaped, etc.

Modem day integrated chips comprise millions or billions of semiconductor devices formed on a semiconductor substrate (e.g., silicon). Integrated chips (ICs) may use many different types of semiconductor devices, depending on an application of an IC.

To manufacture ICs and/or IC dies, a plurality of semiconductor chip regions are marked on a substrate by scribe lines between chip regions. The substrate goes through a variety of cleaning, layering, patterning, etching and doping steps to form integrated circuits. In some embodiments, the bulk substrate includes silicon or a compound semiconductor, such as GaAs, InP, Si/Ge, or SiC. Examples of such layers include dielectric layers, doped layers, polysilicon layers or conductive layers. Examples of device structures include transistors, resistors, and/or capacitors, which may be interconnected through an interconnect layer to additional integrated circuits.

This disclosure, and the example embodiments described herein, relate to semiconductor substrate/wafer/die capacitor structures. According to some example embodiments, this disclosure, and the example embodiments described herein, relate to semiconductor substrate/wafer/die 3D MIM capacitor structures. According to some example embodiments, a MIM capacitor structure and methods of forming the same, are disclosed that includes a vertical cylindrical capacitor MIM structure that has, at a minimum, a) an inner cylindrical capacitor structure and b) an outer cylindrical capacitor structure which encircles the inner cylindrical capacitor structure.

Described herein is a multilayer film stacking design utilizing a plurality of conductive tubes. The plurality of conductive tubes are nested within each other with adjacent tubes spaced from each other by a dielectric gap region to increase the surface area of the resulting capacitor structure for a given area, relative to other semiconductor capacitor structures including other deep trench capacitor structures (DTC). The result is a boost in capacitance of the disclosed tube-in-tube capacitor structure. In other words, the disclosed tub-in-tube capacitor structure provides a relative increase in capacitance density achievable for a semiconductor structure, device or IC integrating a tube-in-tube capacitor structure. Some possible uses of the disclosed MIM tube-in-tube capacitor structure include, but are not limited to, CMOS image sensors, DRAM, Power Devices, etc.

The capacitance of a particular capacitor structure is generally calculated as C=ϵA/d, where the dielectric coefficient ϵ is a measure of the electric polarizability of a dielectric material sandwiched between two conductor plates; surface area A is the surface area of the conductor plate/dielectric material interface; and d is the distance between the two conductive plates.

Previous designs of semiconductor type capacitor structures are designed to improve the capacitance density of a semiconductor device by having deep trenches for housing the capacitor structure plates and dielectric material, thereby increasing the surface area A, or fabricating a plurality of densely spaced vias to provide an increase in capacitance density for the semiconductor device.

In contrast to, and distinguishable from, the tube-in-tube capacitor structure disclosed herein provides more conductor/dielectric interface surface area using one or more inner conductive tubes, thereby increasing the relative capacitance density of the capacitance structure. In addition, by increasing the overall size of a via opening, the process of subsequent layering of conductive layers is more efficient and relatively more accommodated by existing fabrication techniques and processes.

According to another aspect of the disclosure, a structure and method of forming the same, is provided to manufacture a tube-in-tube capacitor structure from an incomplete semiconductor structure or device, where preexisting/previously formed vias are etched out to create enlarged vias with an increased diameter opening for creating and stacking a plurality of conductor tube-in-tube films, prior to depositing dielectric material between the nested conductive tubes. Some examples of achievable attributes associated with the resulting tube-in-tube structures include, but are not limited to, a 6, 8, 10, 12, or more capacitor sidewall configuration, where some example embodiments have a capacitor structure pitch of about a 0.4 um with a 10 sidewall configuration, including a 0.04 um spacing between each tube-in-tube MIM capacitor cavity structure. In contrast, a 4 sidewall capacitor structure, without the use of a tube-in-tube structure as disclosed herein, requires about 0.24 um per pitch (i.e. center-to-center distance between adjacent capacitor structures) The increase in the capacitance area ratio of the tube-in-tube capacitance structure, according to some example embodiments, relative to the 4 sided non-tube-in-tube capacitance structure, is about 1:1.5, or an area ratio increase of about 50% or more. Furthermore, the capacitance of the disclosed tube-in-tube capacitor structure can achieve a capacitance of 1200 fF or more.

According to some embodiments, the structures disclosed herein include, but are not limited to, the following.

Embodiment 1 (Structure): A semiconductor capacitor structure having outer (1^{s} conductive layer) and inner (2^{nd} conductive layer) tubular shaped conductors/electrodes that share a common connection region and act as a first plate/electrode of the capacitor structure, the outer and inner tubular shaped conductors/electrodes formed with a first gap region between the outer and inner tubular shaped conductors/electrodes and a second gap region within an inner region of the inner tubular shaped conductors/electrode, wherein the first gap region and the second gap region are filled/lined with a capacitor dielectric material and a conductor material deposited on the filled/lined dielectric material to act as a second plate/electrode of the capacitor structure.

Embodiment 2 (Structure): A semiconductor capacitor structure having three or more tubular shaped conductors/electrodes that share a common connection region and act as a first plate/electrode of the capacitor structure, the tubular shaped conductors/electrodes formed with a first gap region between adjacent first (i.e. outer) and second tubular shaped conductors/electrodes, a second gap region between adjacent second and third tubular shaped conductors/electrodes, and a third gap region within an inner region of the third (i.e., inner) tubular shaped conductors/electrode, wherein the first gap region, the second gap region and the third gap region are filled/lined with a capacitor dielectric material and a conductor material deposited on the filled/lined dielectric material to act as a second plate/electrode of the capacitor structure.

Embodiment 3 (Method): Method and/or processing to form various stages of Embodiments 1-2, etc., including the deposition of an oxide material/layer on a single tubular shaped conductors/electrode layer (e.g. outer tubular shaped conductors/electrode) prior to forming the next tubular shaped conductors/electrode layer ((e.g. inner tubular shaped conductors/electrode). The method further includes removing the oxide material/layers after the formation of all tubular shaped conductors/electrode layers, thereby creating gap regions between the tubular shaped conductors/electrodes (i.e., tube-in-tube structure) which act as a first plate/electrode of the capacitor structure. The method further includes filling/lining the gap regions with a capacitor dielectric material and a conductor material deposited on the filled/lined dielectric material to act as a second plate/electrode of the capacitor structure.

According to an example embodiment, the tube-in-tube capacitor structures and operatively associated device structures are formed on one or more wafers made of a semiconducting material, where the semiconductor structures are built or formed thereon by conventional semiconductor fabrication techniques, including but not limited to photolithographic techniques such as applying a pattern/structure in a given layer by applying a photoresist layer, patterning the photoresist layer, developing the photoresist layer, and then etching, followed by planarizing and cleaning. While the specific semiconductor fabrication processes required to form the disclosed embodiments shown and described are not the focus of this disclosure, for completeness a general description of the semiconductor fabrication processes follows.

The semiconductor substrate materials can include silicon, for example in the form of crystalline Si or polycrystalline Si. In alternative embodiments, the substrate can be made of other elementary semiconductors such as germanium, or may include a compound semiconductor such as silicon carbide (SiC), gallium arsenide (GaAs), gallium carbide, gallium phosphide, indium arsenide (InAs), indium phosphide (InP), silicon germanium, silicon germanium carbide, gallium arsenic phosphide, or gallium indium phosphide. In particular embodiments, the wafer substrate is silicon.

Generally, a photoresist layer may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the resist evenly from the center of the substrate to the perimeter of the substrate. The rotating speed of the platen is then fixed, which can control the thickness of the final photoresist layer.

Next, the photoresist composition is baked or cured to remove the solvent and harden the photoresist layer. In some particular embodiments, the baking occurs at a temperature of about 90 °C to about 110 °C. The baking can be performed using a hot plate or oven, or similar equipment. As a result, the photoresist layer is formed on the substrate.

The photoresist layer is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer.

An additional photoresist bake step (post exposure bake, or PEB) may occur after the exposure to radiation. For example, this may help in releasing acid leaving groups (ALGs) or other molecules that are significant in chemical amplification photoresist.

The photoresist layer is then developed using a developer. The developer may be an aqueous solution or an organic solution. The soluble portions of the photoresist layer are dissolved and washed away during the development step, leaving behind a photoresist pattern. One example of a common developer is aqueous tetramethylammonium hydroxide (TMAH). Other developers may include 2-heptanone, n-butyl acetate, isoamyl acetate, cyclohexanone, 5-methyl-2-hexanone, methyl-2-hydroxyisobutyrate, ethyl lactate or propylene glycol monomethyl ether acetate, n-pentyl acetate, n-butyl propionate, n-hexyl acetate, n-butyl butyrate, isobutyl butyrate, 2,5-dimethyl-4-hexanone, 2,6-dimethyl-4-heptanone, propyl isobutyrate, or isobutyl propionate. Generally, any suitable developer may be used. Sometimes, a post develop bake or “hard bake” may be performed to stabilize the photoresist pattern after development, for optimum performance in subsequent steps.

Continuing, portions of the layer below the patterned photoresist layer are now exposed. Etching transfers the photoresist pattern to the layer below the patterned photoresist layer. After use, the patterned photoresist layer can be removed, for example, using various solvents such as N-methyl-pyrrolidone (NMP) or alkaline media or other strippers at elevated temperatures, or by dry etching using oxygen plasma.

Generally, any etching step used herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), trifluoromethane (CHF₃), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), oxygen (O₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), nitrogen trifluoride (NF₃), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

Planarizing may be performed to obtain a flat surface. The planarizing may be performed, for example, using a chemical mechanical polishing (CMP) process. Generally, CMP is performed using a rotating platen to which a polishing pad is attached. The substrate is attached to a rotating carrier. A slurry or solution containing various chemicals and abrasives is dispensed onto the polishing pad or the wafer substrate. During polishing, both the polishing pad and the carrier rotate, and this induces mechanical and chemical effects on the surface of the wafer substrate and/or the top layer thereon, removing undesired materials and creating a highly level surface. A post-CMP cleaning step is then carried out using rotating scrubber brushes along with a washing fluid to clean one or both sides of the wafer substrate.

Finally, cleaning steps such as wet cleaning may be performed between various processing steps. The cleaning solution will depend on the etch recipe and the exposed layers. Examples of cleaning solutions may include deionized water, dilute HF, and other conventional solutions.

Dielectric structures or layers of the devices disclosed can be made from any suitable combination of dielectric materials. Examples of dielectric materials may include silicon dioxide (SiO₂), silicon nitride (Si₃N₄), silicon carbide (SiC), hafnium dioxide (HfO₂), zirconium dioxide (ZrO₂), aluminum oxide (Al₂O₃), silicon oxynitride (SiOₓN_{y}), hafnium oxynitride (HfOₓN_{y}) or zirconium oxynitride (ZrOₓN_{y}), or hafnium silicates (ZrSiₓO_{y}) or zirconium silicates (ZrSiₓO_{y}) or silicon carboxynitride (SiCₓO_{y}N_{z}), or hexagonal boron nitride (hBN). Other dielectric materials may include tantalum oxide (Ta₂O₅), nitrides such as silicon nitride, polysilicon, phosphosilicate glass (PSG), fluorosilicate glass (FSG), undoped silicate glass (USG), high-stress undoped silicate glass (HSUSG), and borosilicate glass (BSG).

Any electrically conductive material, discussed herein, may generally be any conductive metal or conductive oxide. Examples of suitable metals may include copper, aluminum, nickel, chromium, gold, germanium, silver, titanium, tungsten, platinum, tantalum, ruthenium, cobalt, rhenium, palladium, or zirconium; composites like TiN, WN, or TaN; or alloys thereof like AlCu. Examples of suitable conductive oxides may include indium tin oxide (ITO), zinc oxide (ZnO), tin oxide (SnO), aluminum zinc oxide (AlZnO), indium oxide (InO), or cadmium oxide (CdO). The metal or oxide material may be deposited, for example, via evaporation or sputtering, plating, chemical vapor deposition (CVD), physical vapor deposition (PVD), atomic layer deposition (ALD), or other suitable methods.

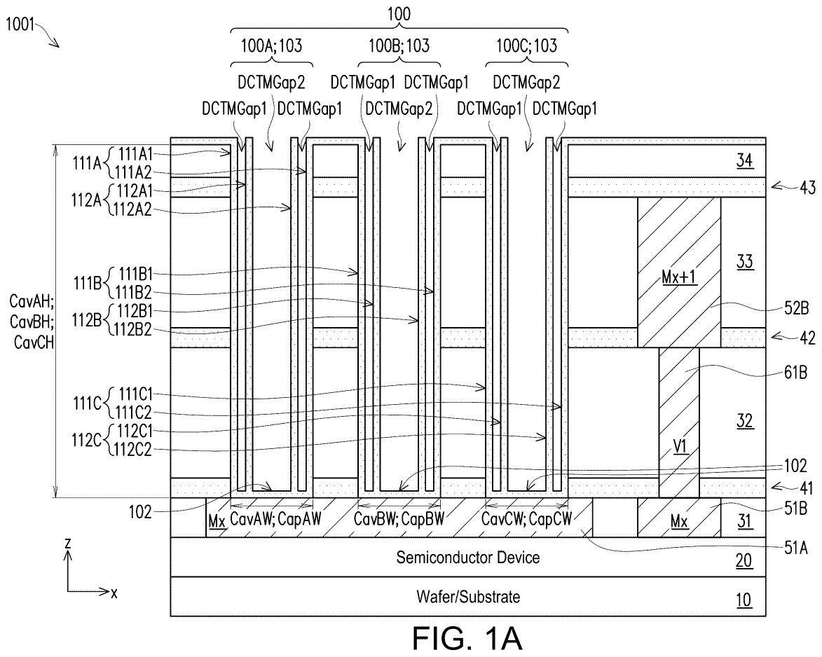

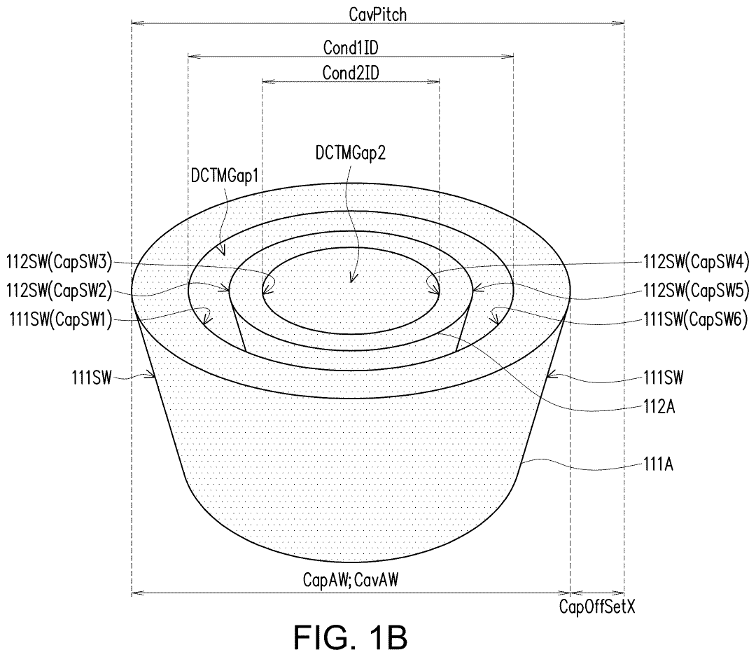

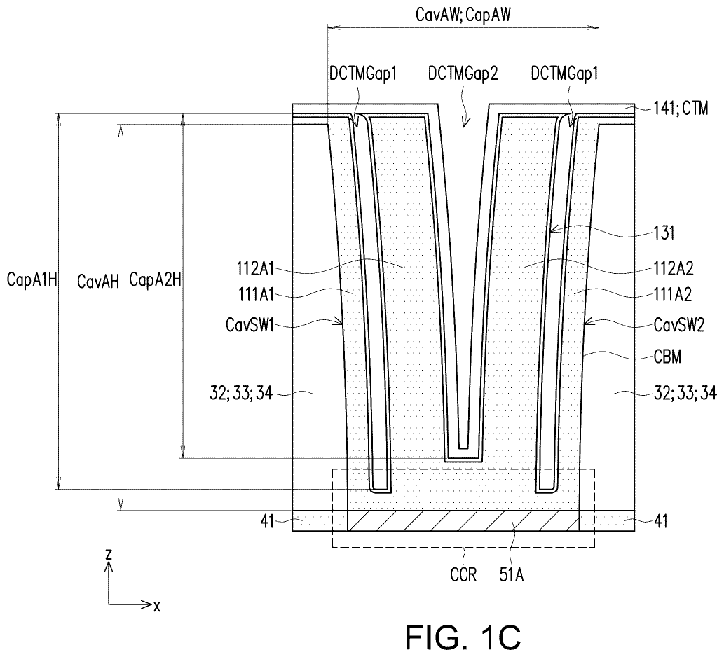

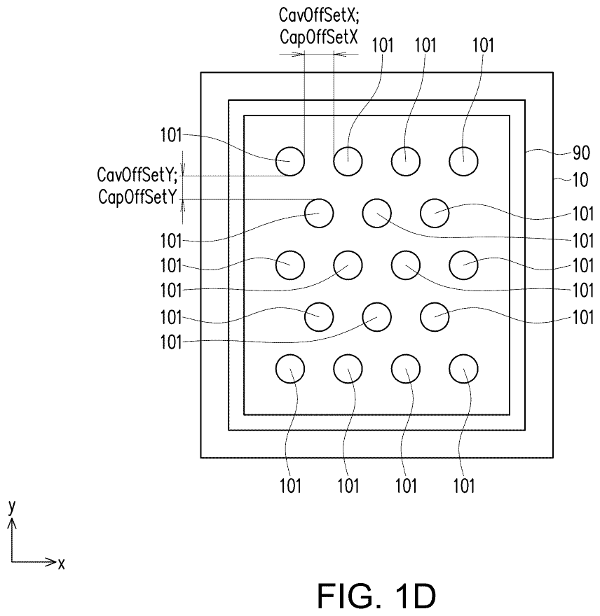

With reference to FIGS. 1A, 1B, 1C and 1D, shown are views of a MIM capacitor structure including six capacitor bottom conductor sidewalls according to an example embodiment of this disclosure, the MIM capacitor structure (Embodiment 1) including one or more etched cavities formed within a dielectric region or substrate, where the MIM capacitor structure is formed within the cavities using a tube-in-tube conductor structure, wherein the tube-in-tube structure includes a plurality of gap regions between the tubes for the deposition of a capacitor dielectric material and capacitor top electrode layer. FIG. 1A shows a cross sectional view of Embodiment 1, FIG. 1B shows a perspective view of a tube-in-tube conductor structure, FIG. 1C shows another detail cross sectional view of an example tube-in-tube capacitor structure, and FIG. 1D shows a top view of an IC/substrate including a plurality of vias associated with an incomplete semiconductor die/substrate which etched are enlarged to accommodate a MIM capacitor structure according to an example embodiment of this disclosure.

Referring to FIG. 1A, as shown, this example embodiment includes a multilayered tube-in-tube/cylinder-in-cylinder/cavity-in-cavity MIM capacitor structure 100, prior to deposition of a capacitor dielectric material, e.g., HK dielectric material such as a layered/sandwiched ZrO2/AlO2/ZrO2 structure, formed within one or dielectric/IME regions 32, 33 and 34 which are formed on oxide dielectric region 31. A semiconductor device 20, formed on a semiconductor wafer/substate 10, interfaces with dielectric region 31 having patterned metallization lines Mx 51A and 51B which connect to capacitor cavities 100A, 100B and 100C which are defined by capacitor sidewalls (see FIG. 1C CavSW1 and CavSW2) to have cavity widths of CavAW, CavBW and CavCW. The cavities shown are formed by an etching process where each of the cavities/capacitor structures 100A, 100B and 100C have an etched height of CavAH, CavBH and CavCH, respectively.

While not required for the operation of a tube-in-tube capacitor structure as described herein, this embodiment further includes etch stop layers 41, 42, and 43, and metallization line Mx+1 52B and via V1 61B which provide electrical connectivity to one or more device structures (not shown) formed within the semiconductor device 20, for example, but not limited to, capacitors, resistors, transistors, etc.

Prior to the deposition of a capacitor dielectric material and top electrode/conductor layer for completing the tube-in-tube capacitor structure, a plurality of nested and spaced tubes are formed within each capacitor area/cavity 100A, 100B and 100C, where 1) capacitor area/cavity 100A includes conductive layer 111A1 and 111A2 form a continuous outer tube conductor structure, conductive layer 112A1 and 112A2 form a continuous inner tube conductor structure, 2) capacitor area/cavity 100B includes conductive layer 111B1 and 111B2 form a continuous outer tube conductor structure, conductive layer 112B1 and 112B2 form a continuous inner tube conductor structure, and 3) capacitor area/cavity 100C includes conductive layer 111C1 and 111C2 form a continuous outer tube conductor structure, conductive layer 112C1 and 112C2 form a continuous inner tube conductor structure. As shown, the tube-in-tube capacitor structures 100A, 100B and 100C each have a width of CapAW, CapBW and CapCW, respectively, which are about equal to the corresponding cavity widths CavAW, CavBW and CavCW.

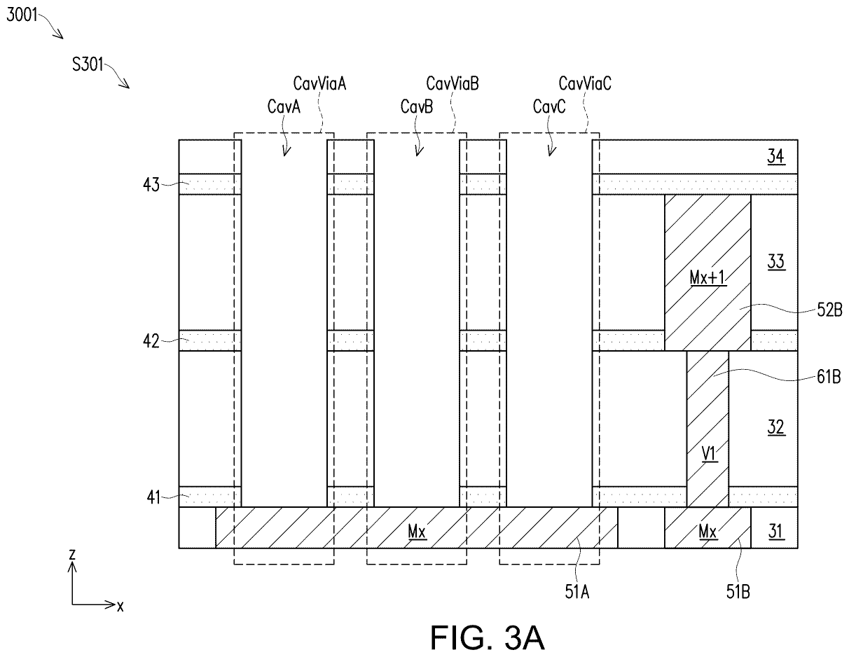

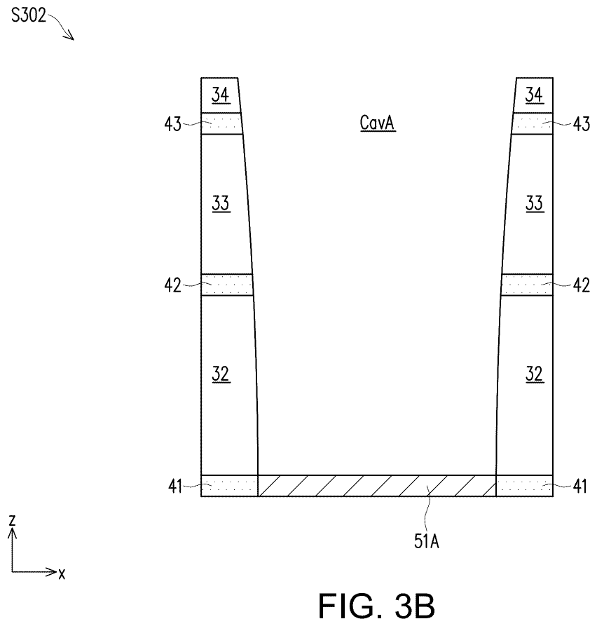

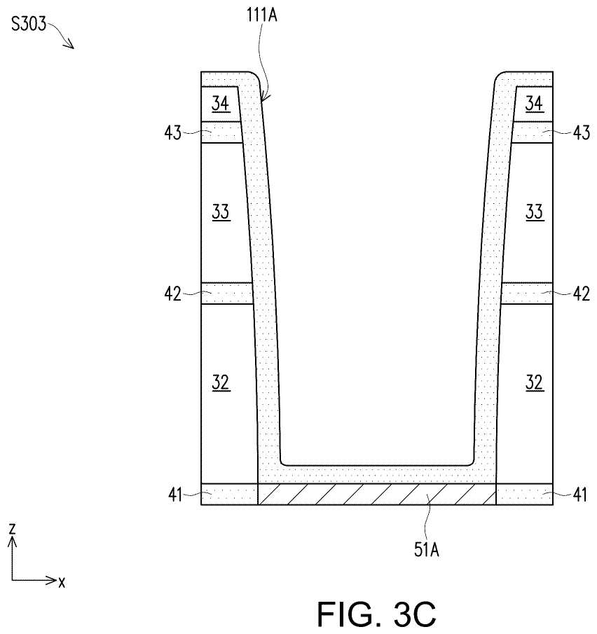

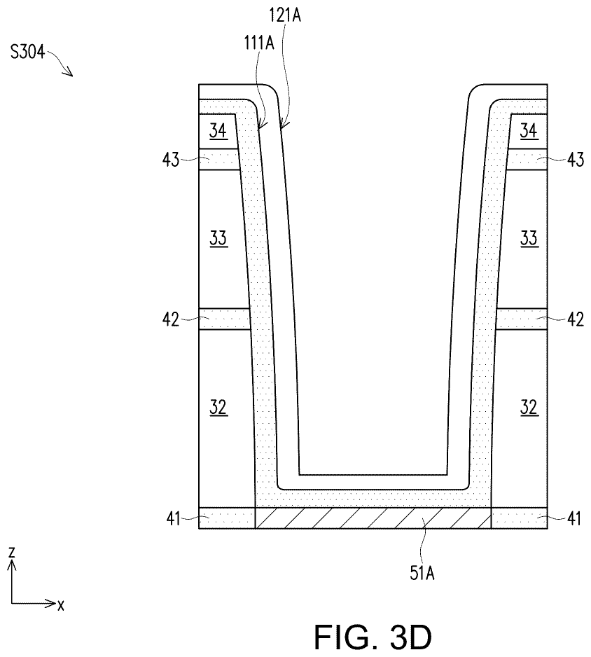

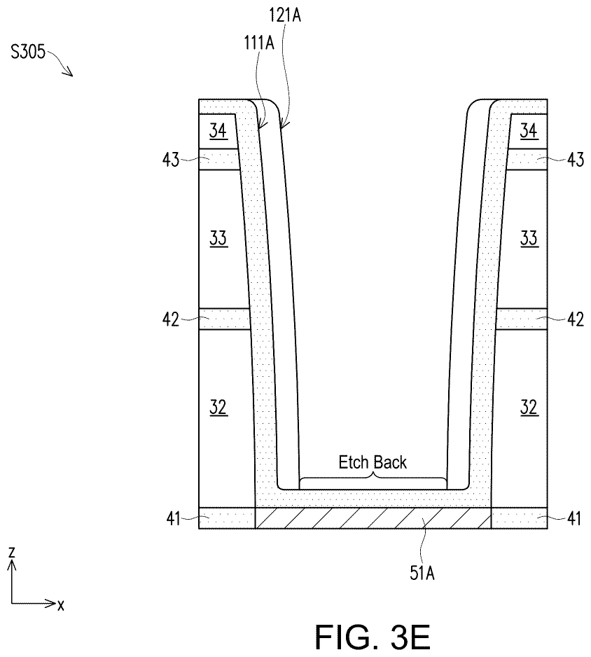

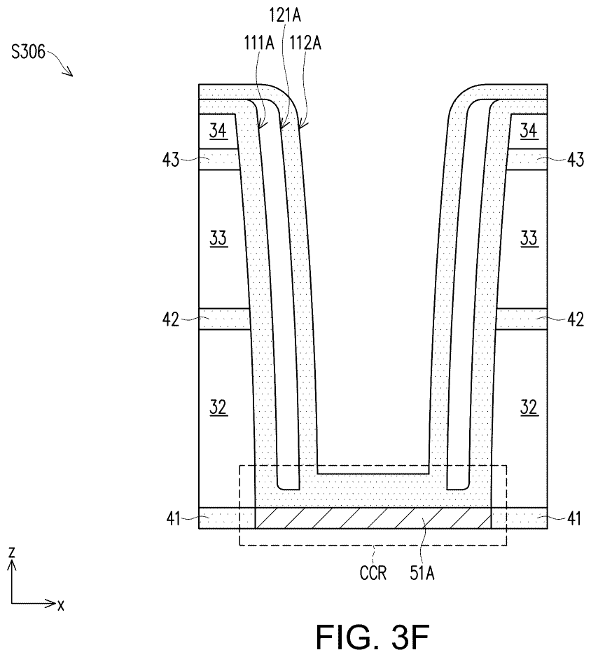

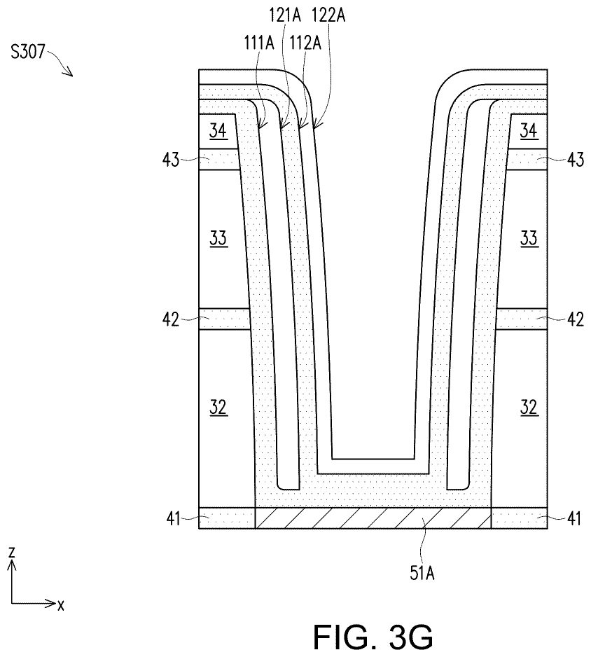

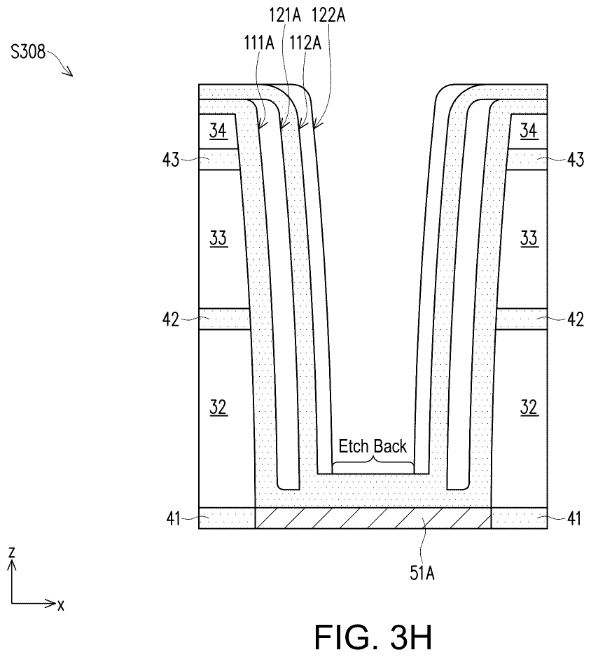

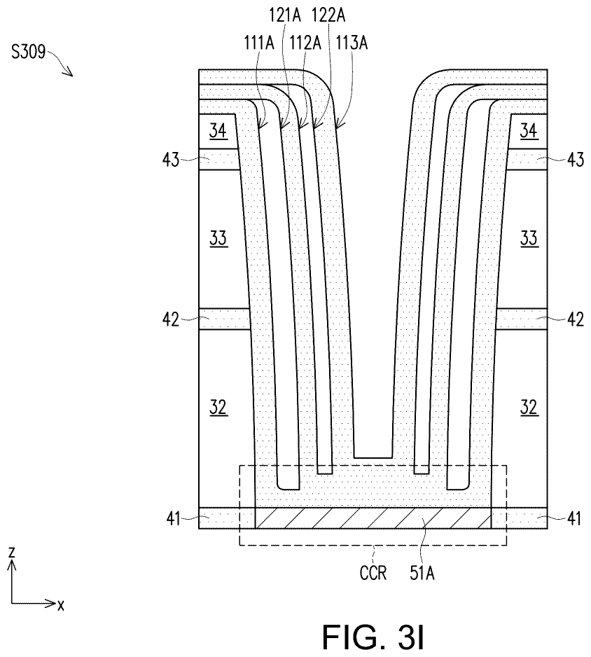

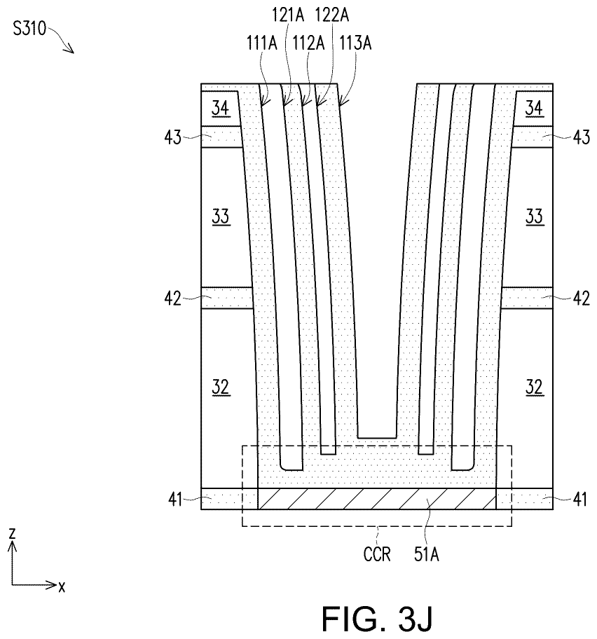

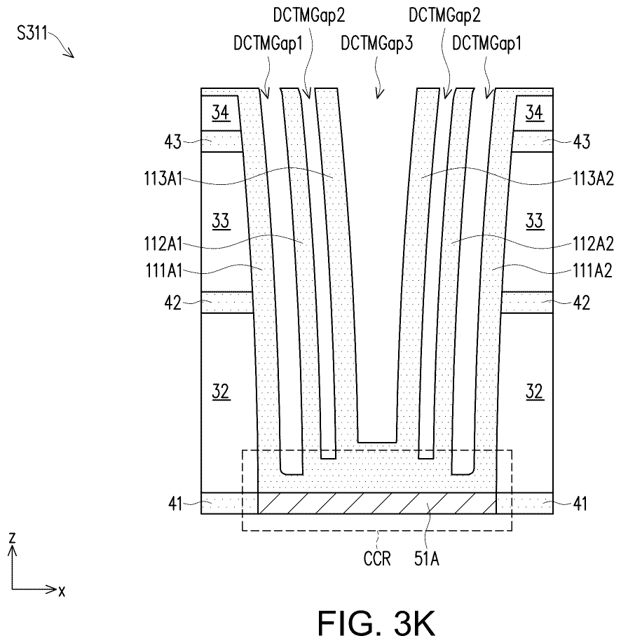

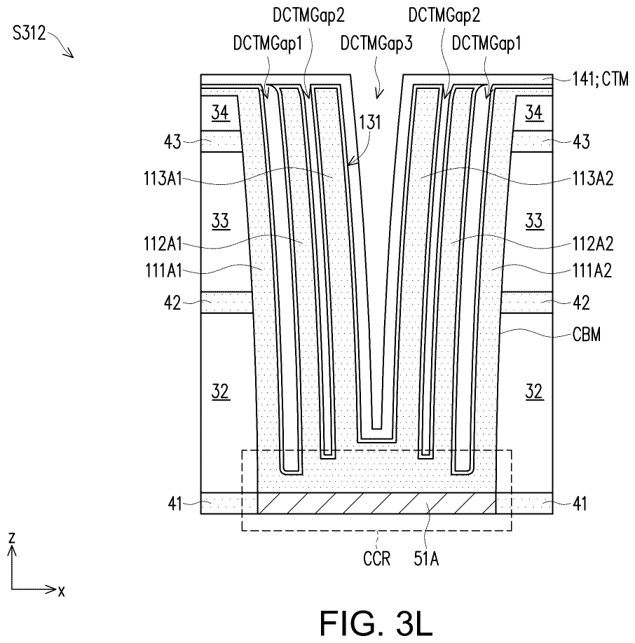

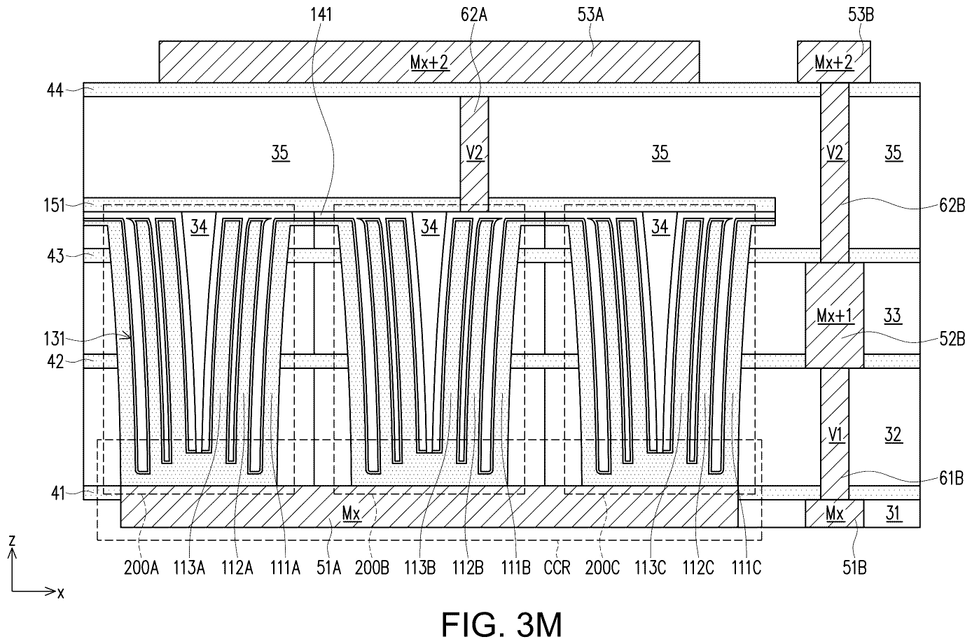

As will be further described herein with reference to FIGS. 3A-3M, the conductor tubes 111A (111A1 and 111A2), 112A (112A1 and 112A2), 111B (111B1 and 111B2), 112B (112B1 and 112B2), 111C (111C1 and 111C2), and 112C (112C1 and 112C2) are formed sequentially using an oxide layer deposit and removal process. Specifically, according to some example embodiments, the outer conductors 111A, 111B and 111C are deposited on the inside surface of the cavities 100A, 100B and 110C, respectively. Then, an oxide film (see FIGS. 3D, 121A) is formed on the outer conductors 111A, 111B and 111C. After the oxide film is formed on outer conductors 111A, 111B and 11C, the inner conductors 112A, 112B and 112C are deposited on the oxide film (see FIGS. 3F, 121A). Then, the oxide film is removed after all the conductors 111A (111A1 and 111A2), 112A (112A1 and 112A2), 111B (111B1 and 111B2), 112B (112B1 and 112B2), 111C (111C1 and 111C2), and 112C (112C1 and 112C2) are formed, which results in the structure shown in FIG. 1A including gap regions DCTMGap1 and DCTMGap2 which are subsequently filled with a capacitor HK dielectric material and a top metal electrode layer thereafter.

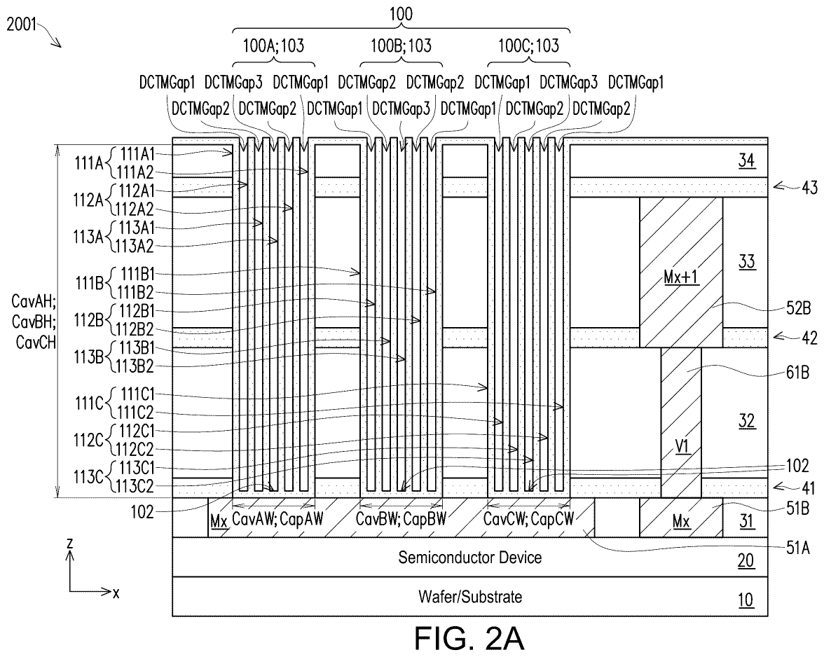

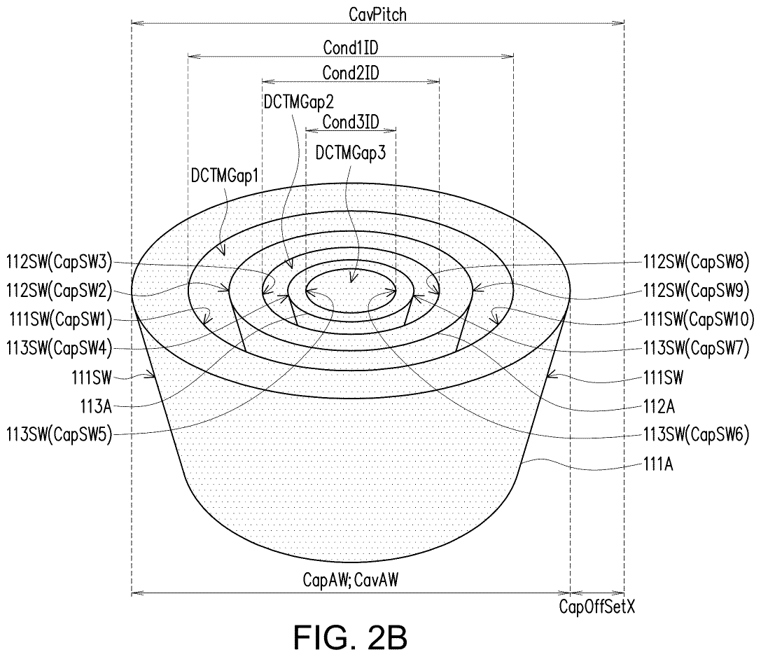

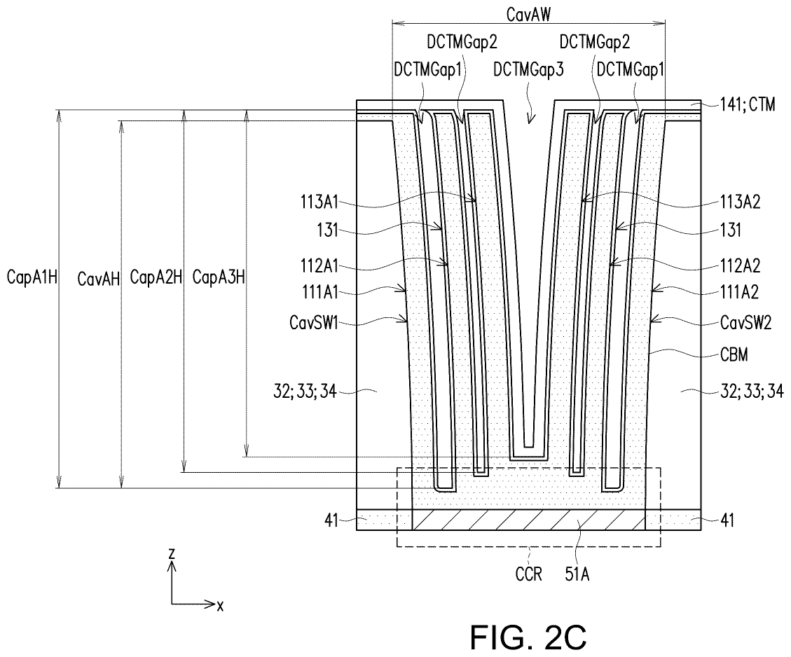

With reference to FIG. 1B, shown are further details of the tube-in-tube capacitor structure 100A, which are also applicable to capacitor structures 100B and 100C. As shown, the resulting tube-in-tube capacitor structure 100A includes a plurality of sidewalls 111SW and 112SW which form the tube-in-tube structure. Sidewalls labeled as CapSW1, CapSW2, CapSW3, CapSW4, CapSW5, and CapSW6 define gap regions DCTMGap1 and DCTMgap2 which are subsequently lined with a HK dielectric material and filled with a top electrode conductive material to complete the functional structure of the capacitor. Other labeled dimensional attributes of the tube-in-tube capacitor structure include 1) cavity offset/capacitor offset CapOffsetX as also shown in FIGS. 1D, 2) cavity/capacitor pitch CavPitch, 3) conductive layer/tube 111A inside diameter Cond1D, and 4) conductive layer/tube 112A inside diameter Cond2ID.

FIG. 1C shows the resulting tube-in-tube capacitor conductor structure of capacitor structure 100A, which is also representative of capacitor structures 100B and 100C. As described with reference to FIGS. 1A and 1B, a continuous capacitor filler dielectric layer 131 is formed within DCTMGap1 and DCTMgap2. With reference to FIG. 1B as well as FIG. 1C, it is shown that the continuous conformal dielectric layer 131 covers the first continuous conductive sidewall 111SW, the first conductive end surface 51A, the second continuous conductive sidewall 112SW, and the second conductive end surface 51A. A third continuous conductive layer 141 provides a capacitor top metal CTM covering the continuous capacitor filler dielectric layer 141.

Other features and attributes of Embodiment 1, some previously described, are shown in FIG. 1C with reference to tube-in-tube capacitor structure 100A within an oxide/IMD structure 32; 33; 34 having a cavity bound by cavity sidewalls CavSW1 and CavSW2. The tube-in-tube capacitor structure 100A includes an overall cavity height CavAH, a height of the outer conductive layer 111A1; 111A2/dielectric layer 131 interface CapA1H, a height of the inner conductive layer 112A1; 112A2/dielectric layer 131 interface CapA2H which is less than CapA1H, and a top capacitor electrode conductive layer 141; CTM. As shown, the outer conductive layer 111A1; 111A2 and inner conductive layer 112A1; 112A2 share a common connection region CCR operatively connected metal line/contact 51A which acts as a capacitor bottom electrode for the resulting capacitive structure.

With reference to FIG. 1D, shown is a top view of an IC/substrate 10 including a plurality of vias 101 associated with an incomplete semiconductor die/substrate, where the plurality of vias 101 shown have been etched and enlarged to accommodate a MIM tube-in-tube capacitor structure 1001 as described with reference to FIGS. 1A-1C. The resulting die structure further includes an isolation ring 90 encircling the plurality of enlarged vias 101 which are arranged in rows and columns. The enlarged vias 101 are subsequently processed to form tube-in-tube capacitor structures, as previously described, which are offset along the X axis by CavOffSetX and offset along the Y axis by CavOffSetY.

While the example embodiments are described herein using cylindrical shaped tube-in-tube capacitor structures, which have advantages related to mechanical rigidity and area layout, other tube shapes may be used.

According to some example embodiments, the following values/range of values may be used.
CavAH/CavBH/CavCH: from about 16000 A to about 18000 A;
CapOffsetX/CapOffSetY: from about 0.027 um to about 0.033 um;
CavPitch: equal to or greater than about 0.4 um;
CaVAW/CavBW/CavCW: from about 0.355 to about 0.365 um;
HK layer 131 thickness: from about 29 A to about 31 A;
Cond 1ID: about 0.30 um;
Cond 2ID: about 0.18 um;
CBM (111A, 112A) thickness: from about 290 A to about 310 A; and
CTM (141) thickness: from about 260 A to about 280 A.

As described with reference to FIGS. 1A-1D, according to some example embodiments, a tube-in-tube capacitor structure 1001 is provided that includes 1) a dielectric substrate region 32; 33; 34 with at least a first cavity 100A formed in the dielectric substrate region 32; 33; 34, the first cavity including a closed end surface 102, an open end 103 opposite to the closed end surface 102, and a continuous sidewall CavSW1 and CavSW2 extending from the closed end surface 102 to the open end 103 through the dielectric substrate region 32; 33; 34 to form an opening of the open end 103 encircled by the continuous sidewall CavSW1 and CavSW2; 2) a first continuous conductive layer 111A formed on the bottom surface and the continuous sidewall of the first cavity CavSW1 and CavSW2, the first continuous conductive layer 111A including a first continuous conductive sidewall 111SW extending from a first conductive end surface proximate to the first cavity closed end surface 102. Furthermore, the first continuous conductive sidewall 111SW and the first conductive end surface cover the first cavity continuous sidewall CavSW1 and CavSW2 and the first cavity end surface 102, the first continuous conductive layer 111A thereby defining a tubular shaped first conductor inner region encircled by the first continuous conductive layer sidewalls 111SW; 3) a second continuous conductive layer 111B formed within the first conductor inner region, the second continuous conductive layer 111B including a first conductive end surface on the first conductive end surface and spaced apart from the first continuous conductive layer sidewall 111SW to form a first dielectric gap region DCTMGap1, the second continuous conductive layer 111B including a second continuous conductive sidewall 112SW extending from a second conductive end surface formed on the first conductive end surface, proximate to the cavity closed end 102, to the first cavity open end 103, thereby defining a tubular shaped second conductor inner region encircled by the second continuous conductive layer sidewalls 112SW to provide a second dielectric gap region DCTMGap2.

According to some other example embodiments, the cavity lengths CavA1H and widths CavAW of each of the capacitor structures 100A, 110B and/or 100C can be different and will vary depending on the capacitance of the structure desired. In addition, while the capacitance structures 100A, 100B and 100C show cavities having orthogonal/perpendicular sidewalls, relative to the metallization line/contact surface 51A, the cavity sidewalls may be tapered as shown in FIG. 3B, or concave or convex. Furthermore, while the example embodiment includes an outer and inner conductor/electrode tube-in-tube structure, other example embodiments may include three or more nested (i.e., tube-in-tube) conductor/electrode layers where three or more gap regions are formed between the conductor/electrode layers.

With reference to FIGS. 2A, 2B and 2C, shown are views of a MIM capacitor structure including ten capacitor bottom conductor sidewalls according to another example embodiment of this disclosure, the MIM capacitor structure (Embodiment 2) 2001 including one or more etched cavities formed within a dielectric region or substrate 32; 33; 34, where the MIM capacitor structure 200 is formed within the cavities using a tube-in-tube conductor structure (200A; 200B; 200C) including a plurality of gap regions DCTMGap1, DCTMGap2, and DCTMGap3 formed between the conductor tubes for the deposition of a dielectric material. FIG. 2A shows a cross sectional view of Embodiment 2, FIG. 2B shows a perspective view of a tube-in-tube conductor structure according to Embodiment 2, and FIG. 2C shows another detail cross sectional view of an example tube-in-tube capacitor structure according to Embodiment 2.

Many of the features and structures of Embodiment 2 have been previously described with reference to FIGS. 1A-1D and are repeated with reference to FIGS. 2A-2C for clarity. Furthermore, while a separate top view of Embodiment 2 structure is not presented here, the top view of Embodiment 1 shown on FIG. 1D is equally representative of Embodiment 1 1001 and Embodiment 2 2001.

The distinguishing feature of Embodiment 2 is the use of three or more nested (i.e., tube-in-tube) tube shaped conductor/electrode layers where three or more gap regions are formed between the conductor/electrode layers, as compared to Embodiment 1, which uses outer and inner tube shaped conductor/electrode layers.

Referring to FIG. 2A, as shown, this example embodiment includes a multilayered tube-in-tube/cylinder-in-cylinder/cavity-in-cavity MIM capacitor structure 200, prior to deposition of a capacitor dielectric material, e.g., HK dielectric material such as a layered/sandwiched ZrO2/AlO2/ZrO2 structure, formed within one or more dielectric/IMD regions 32, 33 and 34 which are formed on an oxide dielectric region 31. A semiconductor device 20, formed on a semiconductor wafer/substate 10, interfaces with dielectric region 31 having patterned metallization lines Mx 51A and 51B which connect to capacitor cavities 200A, 200B and 200C defined by capacitor sidewalls (see FIG. 2C CavSW1 and CavSW2) to have cavity widths of CavAW, CavBW and CavCW. The cavities shown are formed by an etching process where each of the cavities/capacitor structures 200A, 200B and 200C have an etched height of CavAH, CavBH and CavCH, respectively.

While not required for the operation of a tube-in-tube capacitor structure as described herein, this embodiment further includes etch stop layers 41, 42, and 43, and metallization line Mx+1 52B and via V1 61B which provide electrical connectivity to one or more device structures (not shown) formed within the semiconductor device 20, for example, but not limited to, capacitors, resistors, transistors, etc.

Prior to the deposition of a capacitor dielectric material and top electrode/conductor layer for completing the tube-in-tube capacitor structure, a plurality of nested and spaced tubes are formed within each capacitor area/cavity 200A, 200B and 200C, where 1) capacitor area/cavity 200A includes conductive layer 111A1 and 111A2 forming a continuous first tube conductor structure, conductive layer 112A1 and 112A2 forming a continuous second tube conductor structure, and conductive layer 113A1 and 113A2 forming a third continuous tube conductor structure; 2) capacitor area/cavity 200B includes conductive layer 111B1 and 111B2 forming a continuous first tube conductor structure, conductive layer 112B1 and 112B2 forming a continuous second tube conductor structure, and conductive layer 113B1 and 113B2 forming a third continuous tube conductor structure; and 3) capacitor area/cavity 200C includes conductive layer 111C1 and 111C2 forming a continuous first tube conductor structure, conductive layer 112C1 and 112C2 forming a continuous second tube conductor structure, and conductive layer 113C1 and 113C2 forming a third continuous tube conductor structure. As shown, the tube-in-tube capacitor structures 200A, 200B and 200C each have a width of CapAW, CapBW and CapCW, respectively, which are about equal to the corresponding cavity widths CavAW, CavBW and CavCW.

As will be further described herein with reference to FIGS. 3A-3M, the conductor tubes 111A (111A1 and 111A2), 112A (112A1 and 112A2), 113A (113A1 and 113A2), 111B (111B1 and 111B2), 112B (112B1 and 112B2), 113B (113B1 and 113B2), 111C (111C1 and 111C2), 112C (112C1 and 112C2) and 113C (113C1 and 113C2) are formed sequentially using an oxide layer deposit and removal process. Specifically, according to some example embodiments, the first conductors 111A, 111B and 111C are deposited on the inside surface of cavities 200A, 200B and 210C, respectively. Then, an oxide film (see FIGS. 3D, 121A) is formed on the first conductors 111A, 111B and 111C. After the oxide film is formed on first conductors 111A, 111B and 11C, the second conductors 112A, 112B and 112C are deposited on the oxide film (see FIGS. 3F, 121A and 122A). Then, all oxide films (see FIGS. 3J and 3K, 121A and 122A) are removed after all the conductors 111A, 111B, 111C. 112A, 112B, 112C, 113A, 113B and 113C are formed, which results in the structure shown in FIG. 1A including gap regions DCTMGap1, DCTMGap2 and DCTGap3 which are subsequently filled with a capacitor HK dielectric material.

With reference to FIG. 2B, shown are further details of the tube-in-tube capacitor structure 200A, which are also applicable to capacitor structures 200B and 200C. As shown, the resulting tube-in-tube capacitor structure 200A includes a plurality of sidewalls 111SW, 112SW and 113SW which form the tube-in-tube structure. Sidewalls labeled as CapSW1, CapSW2, CapSW3, CapSW4, CapSW5, CapSW6, CapSW7, CapSW8, CapSW9 and CapSW10 define gap regions DCTMGap1, DCTMGap2 and DCTMgap3 which are subsequently lined with a HK dielectric material and filled with a top electrode conductive material to complete the functional structure of the capacitor. Other labeled dimensional attributes of the tube-in-tube capacitor structure include 1) cavity offset/capacitor offset CapOffsetX as also shown in FIGS. 1D, 2) cavity/capacitor pitch CavPitch, 3) conductive layer/tube 111A inside diameter Cond1D, 4) conductive layer/tube 112A inside diameter Cond2ID, and 4) conductive layer/tube 113A inside diameter Cond3ID.

FIG. 2C shows the resulting tube-in-tube capacitor conductor structure of capacitor structure 200A, which is also representative of capacitor structures 200B and 200C. As described with reference to FIGS. 2A and 2B, a continuous capacitor filler dielectric layer 131 is formed within DCTMGap1, DCTMgap2, and DCTMgap3. With reference to FIG. 2B as well as FIG. 2C, it is shown that the continuous conformal dielectric layer 131 covers the first continuous conductive sidewall 111SW, the first conductive end surface 51A, the second continuous conductive sidewall 112SW, the second conductive end surface 51A, the third continuous conductive sidewall 113SW, and the third conductive end surface 51A A fourth continuous conductive layer 141 provides a capacitor top metal CTM covering the continuous capacitor filler dielectric layer 141.

Other features and attributes of Embodiment 1, some previously described, are shown in FIG. 2C with reference to tube-in-tube capacitor structure 200A within an oxide/IMD structure 32; 33; 34 having a cavity bound by cavity sidewalls CavSW1 and CavSW2, the tube-in-tube capacitor structure 200A including an overall cavity height CavAH, a height of the first conductive layer 111A1; 111A2/dielectric layer 131 interface CapA1H, a height of the second conductive layer 112A1; 112A2/dielectric layer 131 interface CapA2H which is less than CapA1H, a height of the third conductive layer 113A1; 113A2/dielectric layer 131 interface CapA3H which is less than CapA2H and a top capacitor electrode conductive layer 141; CTM. As shown, the first conductive layer 111A1; 111A2, the second conductive layer 112A1; 112A2 and the third conductive layer 113A1; 113A2 share a common connection region CCR operatively connected to metal line/contact 51A which acts as a capacitor bottom electrode for the resulting capacitive structure.

With reference to FIG. 1D, shown is a top view of an IC/substrate 10 including a plurality of vias 101 associated with an incomplete semiconductor die/substrate, where the plurality of vias 101 shown have been etched and enlarged to accommodate a MIM tube-in-tube capacitor structure 2001 as described with reference to FIGS. 2A-2C. The resulting die structure further includes an isolation ring 90 encircling the plurality of enlarged vias 101 which are arranged in rows and columns. The enlarged vias 101 are subsequently processed to form tube-in-tube capacitor structures, as previously described with reference to FIGS. 2A-2C, which are offset along the X axis by CavOffSetX and offset along the Y axis by CavOffSetY.

While the example embodiment 2001 is described using a cylindrical shaped tube-in-tube capacitor structure which has advantages related to mechanical rigidity and area layout, other tube shapes may be used.

According to some example embodiments as described with reference to FIGS. 2A-2C, the following values/range of values may be used.
CavAH/CavBH/CavCH: from about 16000 A to about 18000 A;
CapOffsetX/CapOffSetY: from about 0.027 um to about 0.033 um;
CavPitch: equal to or greater than about 0.4 um;
CavAW/CavBW/CavCW: from about 0.355 to about 0.365 um;
HK layer 131 thickness: from about 29 A to about 31 A;
Cond 1ID: about 0.30 um;
Cond 2ID: about 0.18 um;
Cond 3ID: about 0.06 um;
CBM (111A, 112A, 113A) thickness: from about 290 A to about 310 A; and
CTM (141) thickness: from about 260 A to about 280 A.

With reference to FIGS. 3A, 3B, 3C, 3D, 3E, 3F, 3G, 3H, 3I, 3J, 3K, 3L and 3M, shown is a series of processing stages to manufacture/fabricate a MIM capacitor structure (Embodiment 3) 3001 according to an example embodiment of this disclosure, the process stages applicable to Embodiment 1, Embodiment 2 and other semiconductor structure/devices including a tube-in-tube capacitor structure having 2 or more tubular shaped conductors with at least one inner conductor tube encircled by at least one outer conductor tube. In other words, the processing stages show a multilayer film stacking process within a tubular shaped conductor layer, i.e., hollow tube, to increase the effective capacitor's dielectric/conductor surface area to provide an improved/greater capacitance structure.

FIG. 3A shows an initial state, S301, of a semiconductor structure for processing according to some example embodiments of this disclosure. To form the semiconductor structure shown in FIG. 3A, a plurality of semiconductor lithographic processes are used, including but not limited to, photoresist patterning, exposure and development, material deposition processes, etching processes, etc. to form etched vias CavViaA, CavViaB and CavViaC, which may be enlarged by an etch process from an initial incomplete semiconductor structure. As shown, the initial incomplete semiconductor structure includes a plurality of oxide/IMD/dielectric regions 31, 32, 33 and 34, where etch stop layers 41, 42 and 43, e.g., SIC layers, are used during the fabrication process. While not required for the operation of a tube-in-tube capacitor structure as described herein, this embodiment further includes etch stop layers 41, 42, and 43, and metallization line Mx+1 52B and via V1 61B which provide electrical connectivity to one or more device structures (not shown) formed within, for example, a semiconductor device 20 as shown in FIGS. 1A and 2A. Example processes used to form the structure shown in FIG. 3A include the use of an amorphous carbon hard mask (APF) to perform a tri-layer hole etch and/or plasma etch process to create the vias/cavities CavA, CavB and CavC of the initial incomplete semiconductor structure.

FIGS. 3B-3L show a series of the example stages of the fabrication of a tube-in-tube capacitor structure 100A/200A as previously described, with the understanding that the stages/steps/processes also are applicable to the forming of tube-in-tube capacitor structures 100B/200B and 100C/200C as well.

According to some example embodiments, as shown in FIG. 3B S302, the tube-in-tube capacitor structure is formed or fabricated from an initial mask and etching of vias (outlined as CavA, CavB and CavC) as shown in stage S301 to widen the tubes/cavities CavA, CavB and CavC for a multilayering process to form a tube-in-tube capacitor structure 1001; 2001 as previously described.

FIG. 3C S303 shows the widened cavity CavA where a first tubular shaped conductor layer 111A is deposited within CavA on the sidewalls of CavA, for example by depositing Tn.

FIG. 3D S304 shows the deposition of a first oxide layer 121A on the first conductor layer 111A, e.g., ALD oxide deposition or plasma vapor deposition.

FIG. 3E S305 shows where an oxide etch back process is performed to remove/dress the oxide layer 121A using, for example, a vapor phase high frequency (VHF) process Specifically, an oxide etch back process is performed to remove/dress the oxide layer 121A near the bottom of the CavA in preparation for the depositing of a second tubular shaped conductor layer 112A as shown in FIG. 3F S306, e.g., TiN deposition. Stage S306 layers the second tubular shaped conductor layer 112A such that it shares a common connection region CCR with the first tubular shaped conductor layer 111A.

FIGURE S307 3G shows the deposition of a second oxide layer 122A on the first conductor layer 111A, e.g., ALD oxide deposition or plasma vapor deposition, similar to the process performed at stage S303.

FIG. 3H S308 shows where an oxide etch back process is performed to remove/dress the oxide layer 122A, as previously described in step S305, near the bottom of the CavA in preparation for the depositing of a third tubular shaped conductor layer 113A as shown in FIG. 3I S309, e.g., TiN deposition. Stage S309 layers the third tubular shaped conductor layer 113A such that it shares a common connection region CCR with the first tubular shaped conductor layer 111A and the second tubular shaped conductor layer 112A.

FIG. 3J S310 shows a stage of the structure after performing an etch back process and/or CMP process on the top conductor region of the structure to expose oxide layers 121A, 122A and 123A for removal as shown in FIG. 3K S311, thereby creating gap regions DCTGap1, DCTGap2 and DCTGap3.

FIG. 3L S311 shows a final stage of the tube-in-tube capacitor structure without any external electrical interface or connection, where a HK dielectric material 131 is deposited within gap regions DCTGap1, DCTGap2 and DCTGap3 shown in FIG. 3K, and a further conductor/electrode layer is deposited to cover the HK dielectric material 131, further conductor/electrode layer functioning as a capacitor top electrode CTM.

FIG. 3M S312 shows a final stage of the tube-in-tube capacitor structure with an example electrical interfaces and connections. As shown, the tube-in-tube capacitor structure formed as shown in stage S311 and further described with reference to FIGS. 2A-2C above, is further processed to form SiN protective layers 44 and 151, an additional oxide/IMD/dielectric region 35, patterned metallization layers 53A and 53B, and vias 62A and 62B providing electrical connections to the patterned metallization layers 53A and 53B. In addition, oxide region 34, according to this example embodiment, covers the center or core region of the resulting tube-in-tube capacitor structure. Furthermore, as shown in FIG. 3M, all the tube-in-tube capacitor structures 200A, 200B and 200C are interconnected to provide a single capacitor structure.

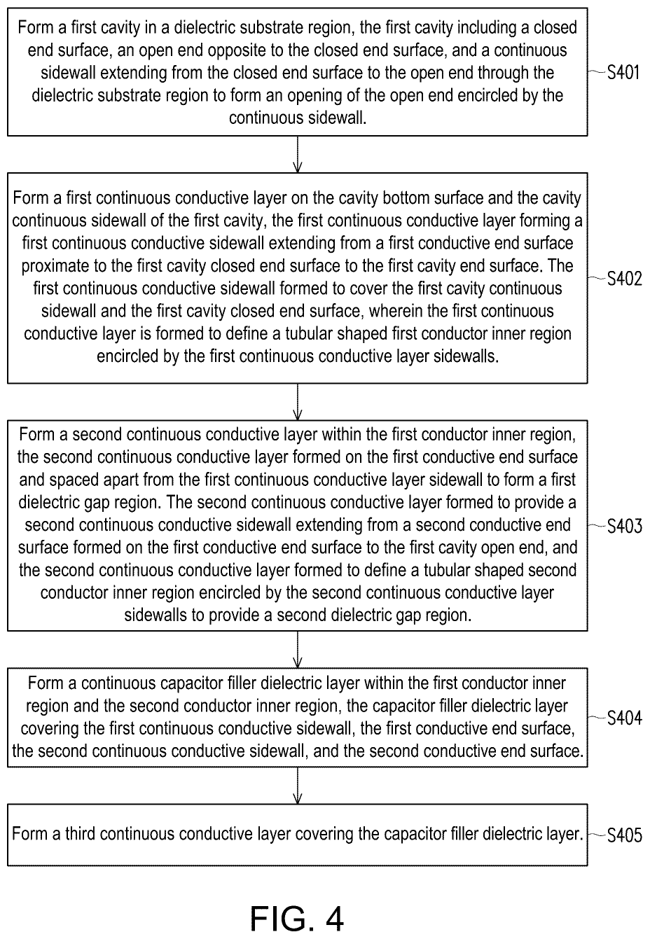

With reference to FIG. 4, shown is a flow chart of a method of forming a capacitor structure according to an example embodiment of this disclosure, the capacitor structure formed with two or more continuous conductive layers to provide a tube-in-tube capacitor structure.

At step S401, the method forms a first cavity in a dielectric substrate region, the first cavity including a closed end surface, an open end opposite to the closed end surface, and a continuous sidewall extending from the closed end surface to the open end through the dielectric substrate region to form an opening of the open end encircled by the continuous sidewall.

At step S402, the method forms a first continuous conductive layer on the cavity bottom surface and the cavity continuous sidewall of the first cavity, the first continuous conductive layer forming a first continuous conductive sidewall extending from a first conductive end surface proximate to the first cavity closed end surface to the first cavity end surface. The first continuous conductive sidewall formed to cover the first cavity continuous sidewall and the first cavity closed end surface, wherein the first continuous conductive layer is formed to define a tubular shaped first conductor inner region encircled by the first continuous conductive layer sidewalls.

At step S403, the method forms a second continuous conductive layer within the first conductor inner region, the second continuous conductive layer formed on the first conductive end surface and spaced apart from the first continuous conductive layer sidewall to form a first dielectric gap region. The second continuous conductive layer formed to provide a second continuous conductive sidewall extending from a second conductive end surface formed on the first conductive end surface to the first cavity open end, and the second continuous conductive layer formed to define a tubular shaped second conductor inner region encircled by the second continuous conductive layer sidewalls to provide a second dielectric gap region.

At step S404, the method forms a continuous capacitor filler dielectric layer within the first conductor inner region and the second conductor inner region, the capacitor filler dielectric layer covering the first continuous conductive sidewall, the first conductive end surface, the second continuous conductive sidewall, and the second conductive end surface.

At step S405, the method forms a third continuous conductive layer covering the capacitor filler dielectric layer.

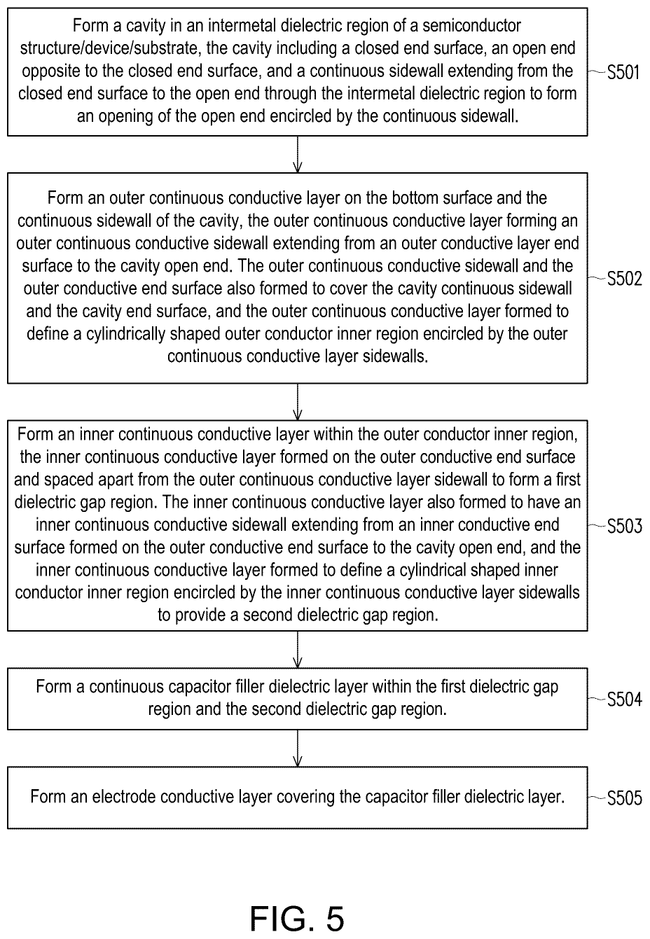

With reference to FIG. 5, shown is a flow chart of another method of forming a capacitor structure according to an example embodiment of this disclosure, the capacitor structure, the capacitor structure formed with two or more continuous conductive layers to provide a tube-in-tube capacitor structure.

At step S501, the method forms a cavity in an intermetal dielectric region of a semiconductor structure/device/substrate, the cavity including a closed end surface, an open end opposite to the closed end surface, and a continuous sidewall extending from the closed end surface to the open end through the intermetal dielectric region to form an opening of the open end encircled by the continuous sidewall.

At step S502, the method forms an outer continuous conductive layer on the bottom surface and the continuous sidewall of the cavity, the outer continuous conductive layer forming an outer continuous conductive sidewall extending from an outer conductive layer end surface to the cavity open end. The outer continuous conductive sidewall and the outer conductive end surface also formed to cover the cavity continuous sidewall and the cavity end surface, and the outer continuous conductive layer formed to define a cylindrically shaped outer conductor inner region encircled by the outer continuous conductive layer sidewalls.

At step S503, the method forms an inner continuous conductive layer within the outer conductor inner region, the inner continuous conductive layer formed on the outer conductive end surface and spaced apart from the outer continuous conductive layer sidewall to form a first dielectric gap region. The inner continuous conductive layer also formed to have an inner continuous conductive sidewall extending from an inner conductive end surface formed on the outer conductive end surface to the cavity open end, and the inner continuous conductive layer formed to define a cylindrical shaped inner conductor inner region encircled by the inner continuous conductive layer sidewalls to provide a second dielectric gap region.

At step S504, the method forms a continuous capacitor filler dielectric layer within the first dielectric gap region and the second dielectric gap region.

At step S505, the method forms an electrode conductive layer covering the capacitor filler dielectric layer.

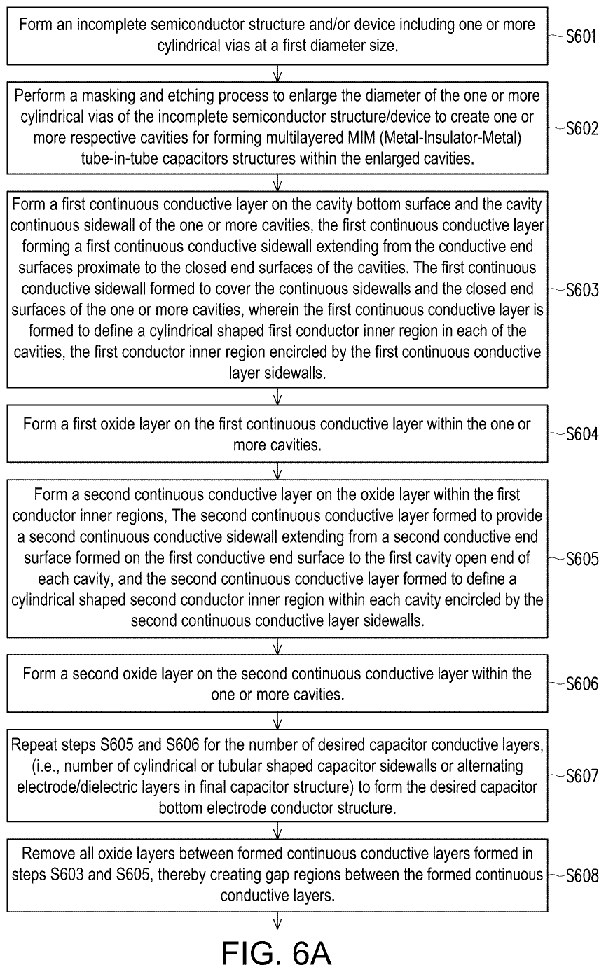

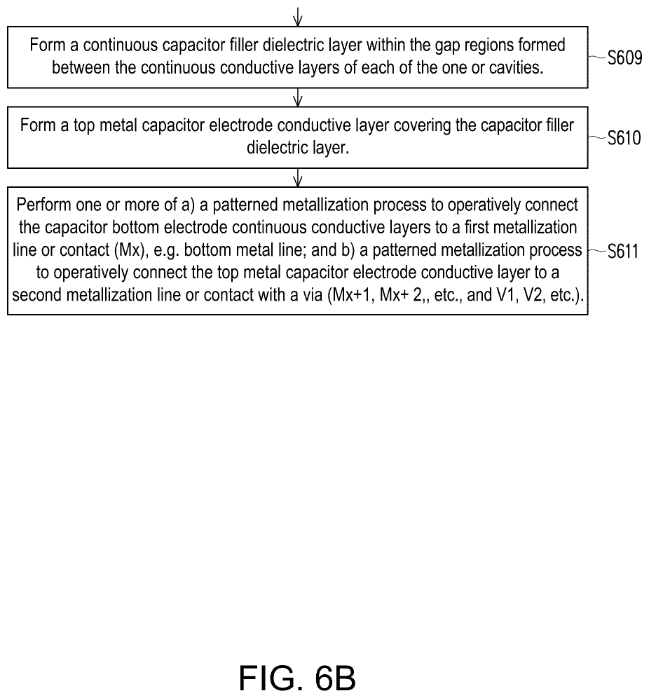

With reference to FIGS. 6A and 6B, in combination, shown is a flow chart of another method of forming a capacitor structure according to an example embodiment of this disclosure, the capacitor structure formed by depositing an oxide layer on a first/outer continuous conductive layer prior to forming the second/inner continuous conductive layer, removing the oxide layer after forming the second/inner continuous conductive layer, and depositing a capacitive dielectric material, e.g. high-k (HK) dielectric material, within a gap region resulting from the removal of the oxide layer.

At step S601, the method forms an incomplete semiconductor structure and/or device including one or more cylindrical vias at a first diameter size.

At step S602, the method performs a masking and etching process to enlarge the diameter of the one or more cylindrical vias of the incomplete semiconductor structure/device to create one or more respective cavities for forming multilayered MIM tube-in-tube capacitors structures within the enlarged cavities.

At step S603, the method forms a first continuous conductive layer on the cavity bottom surface and the cavity continuous sidewall of the one or more cavities, the first continuous conductive layer forming a first continuous conductive sidewall extending from the conductive end surfaces proximate to the closed end surfaces of the cavities. The first continuous conductive sidewall formed to cover the continuous sidewalls and the closed end surfaces of the one or more cavities, wherein the first continuous conductive layer is formed to define a cylindrical shaped first conductor inner region in each of the cavities, the first conductor inner region encircled by the first continuous conductive layer sidewalls.

At step S604, the method forms a first oxide layer on the first continuous conductive layer within the one or more cavities.

At step S605, the method forms a second continuous conductive layer on the oxide layer within the first conductor inner regions, The second continuous conductive layer formed to provide a second continuous conductive sidewall extending from a second conductive end surface formed on the first conductive end surface to the first cavity open end of each cavity, and the second continuous conductive layer formed to define a cylindrical shaped second conductor inner region within each cavity encircled by the second continuous conductive layer sidewalls.

At step S606, the method forms a second oxide layer on the second continuous conductive layer within the one or more cavities.

At step S607, the method repeat steps S605 and S606 for the number of desired capacitor conductive layers, (i.e., number of cylindrical or tubular shaped capacitor sidewalls or alternating electrode/dielectric layers in final capacitor structure) to form the desired capacitor bottom electrode conductor structure.

At step S608, the method removes all oxide layers between formed continuous conductive layers formed in steps S603 and S605, thereby creating gap regions between the formed continuous conductive layers.

At step S609, the method forms a continuous capacitor filler dielectric layer within the gap regions formed between the continuous conductive layers of each of the one or cavities.

At step S610, the method forms a top metal capacitor electrode conductive layer covering the capacitor filler dielectric layer.

At step S611, the method performs one or more of a) a patterned metallization process to operatively connect the capacitor bottom electrode continuous conductive layers to a first metallization line or contact (Mx), e.g. bottom metal line; and b) a patterned metallization process to operatively connect the top metal capacitor electrode conductive layer to a second metallization line or contact with a via (Mx+1, Mx+2, etc., and V1, V2, etc.).

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the disclosed tube-in-tube capacitor structure disclosed herein provides more conductor/dielectric interface surface area using one or more inner conductive tubes, thereby increasing the relative capacitance density of the capacitance structure. In addition, by increasing the overall size of a via opening, the process of subsequent layering of conductive layers is more efficient and relatively more accommodated by existing fabrication techniques and processes.

In the following, some further embodiments are described.

In a nonlimiting illustrative embodiment, a method of forming a capacitor structure comprising: forming a first cavity in a dielectric substrate region, the first cavity including a closed end surface, an open end opposite to the closed end surface, and a continuous sidewall extending from the closed end surface to the open end through the dielectric substrate region to form an opening of the open end encircled by the continuous sidewall; forming a first continuous conductive layer on the bottom surface and the continuous sidewall of the first cavity, the first continuous conductive layer forming a first continuous conductive sidewall extending from a first conductive end surface proximate to the first cavity closed end surface, the first continuous conductive sidewall and the first conductive end surface formed to cover the first cavity continuous sidewall and the first cavity end surface, and the first continuous conductive layer formed to define a tubular shaped first conductor inner region encircled by the first continuous conductive layer sidewalls; forming a second continuous conductive layer within the first conductor inner region, the second continuous conductive layer formed on the first conductive end surface and spaced apart from the first continuous conductive layer sidewall to form a first dielectric gap region, the second continuous conductive layer forming a second continuous conductive sidewall extending from a second conductive end surface formed on the first conductive end surface to the first cavity open end, and the second continuous conductive layer formed to define a tubular shaped second conductor inner region encircled by the second continuous conductive layer sidewalls to provide a second dielectric gap region; and forming a continuous capacitor filler dielectric layer within the first conductor inner region and the second conductor inner region, the capacitor filler dielectric layer covering the first continuous conductive sidewall, the first conductive end surface, the second continuous conductive sidewall, and the second conductive end surface; and forming a third continuous conductive layer covering the capacitor filler dielectric layer.

In another nonlimiting illustrative embodiment, a semiconductor capacitor structure comprising: a dielectric substrate region; a first cavity formed in the dielectric substrate region, the first cavity including a closed end surface, an open end opposite to the closed end surface, and a continuous sidewall extending from the closed end surface to the open end through the dielectric substrate region to form an opening of the open end encircled by the continuous sidewall; a first continuous conductive layer formed on the bottom surface and the continuous sidewall of the first cavity, the first continuous conductive layer including a first continuous conductive sidewall extending from a first conductive end surface proximate to the first cavity closed end surface, the first continuous conductive sidewall and the first conductive end surface covering the first cavity continuous sidewall and the first cavity end surface, and the first continuous conductive layer defining a tubular shaped first conductor inner region encircled by the first continuous conductive layer sidewalls; a second continuous conductive layer formed within the first conductor inner region, the second continuous conductive layer including a first conductive end surface on the first conductive end surface and spaced apart from the first continuous conductive layer sidewall to form a first dielectric gap region, the second continuous conductive layer including a second continuous conductive sidewall extending from a second conductive end surface formed on the first conductive end surface to the first cavity open end, and the second continuous conductive layer defining a tubular shaped second conductor inner region encircled by the second continuous conductive layer sidewalls to provide a second dielectric gap region; and a continuous capacitor filler dielectric layer within the first conductor inner region and second conductor inner region, the continuous conformal dielectric layer covering the first continuous conductive sidewall, the first conductive end surface, the second continuous conductive sidewall, and the second conductive end surface; and a third continuous conductive layer covering the continuous capacitor filler dielectric layer.

In another nonlimiting illustrative embodiment, a method of forming a capacitor structure in an integrated circuit (IC), the method comprising: forming a cavity in an intermetal dielectric region, the cavity including a closed end surface, an open end opposite to the closed end surface, and a continuous sidewall extending from the closed end surface to the open end through the intermetal dielectric region to form an opening of the open end encircled by the continuous sidewall; forming an outer continuous conductive layer on the bottom surface and the continuous sidewall of the cavity, the outer continuous conductive layer forming an outer continuous conductive sidewall extending from an outer conductive layer end surface to the cavity open end, the outer continuous conductive sidewall and the outer conductive end surface formed to cover the cavity continuous sidewall and the cavity end surface, and the outer continuous conductive layer formed to define a cylindrically shaped outer conductor inner region encircled by the outer continuous conductive layer sidewalls; forming an inner continuous conductive layer within the outer conductor inner region, the inner continuous conductive layer formed on the outer conductive end surface and spaced apart from the outer continuous conductive layer sidewall to form a first dielectric gap region, the inner continuous conductive layer forming an inner continuous conductive sidewall extending from an inner conductive end surface formed on the outer conductive end surface to the cavity open end, and the inner continuous conductive layer formed to define a cylindrical shaped inner conductor inner region encircled by the inner continuous conductive layer sidewalls to provide a second dielectric gap region; and forming a continuous capacitor filler dielectric layer within the first dielectric gap region and the second dielectric gap region; and forming an electrode conductive layer covering the capacitor filler dielectric layer.

In another nonlimiting illustrative embodiment, a semiconductor capacitor structure comprising: a dielectric substrate region; a cavity in an intermetal dielectric region, the cavity including a closed end surface, an open end opposite to the closed end surface, and a continuous sidewall extending from the closed end surface to the open end through the intermetal dielectric region to form an opening of the open end encircled by the continuous sidewall; an outer continuous conductive layer on the bottom surface and the continuous sidewall of the cavity, the outer continuous conductive layer forming an outer continuous conductive sidewall extending from an outer conductive layer end surface to the cavity open end, the outer continuous conductive sidewall and the outer conductive end surface formed to cover the cavity continuous sidewall and the cavity end surface, and the outer continuous conductive layer formed to define a cylindrically shaped outer conductor inner region encircled by the outer continuous conductive layer sidewalls; inner continuous conductive layer within the outer conductor inner region, the inner continuous conductive layer formed on the outer conductive end surface and spaced apart from the outer continuous conductive layer sidewall to form a first dielectric gap region, the inner continuous conductive layer forming an inner continuous conductive sidewall extending from an inner conductive end surface formed on the outer conductive end surface to the cavity open end, and the inner continuous conductive layer formed to define a cylindrical shaped inner conductor inner region encircled by the inner continuous conductive layer sidewalls to provide a second dielectric gap region; a continuous capacitor filler dielectric layer within the first dielectric gap region and the second dielectric gap region; and an electrode conductive layer covering the capacitor filler dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a capacitor structure comprising:
forming a first cavity in a dielectric substrate region, the first cavity including a closed end surface, an open end opposite to the closed end surface, and a continuous sidewall extending from the closed end surface to the open end through the dielectric substrate region to form an opening of the open end encircled by the continuous sidewall;
forming a first continuous conductive layer on the bottom surface and the continuous sidewall of the first cavity, the first continuous conductive layer forming a first continuous conductive sidewall extending from a first conductive end surface proximate to the first cavity closed end surface, the first continuous conductive sidewall and the first conductive end surface formed to cover the first cavity continuous sidewall and the first cavity end surface, and the first continuous conductive layer formed to define a tubular shaped first conductor inner region encircled by the first continuous conductive layer sidewalls;
forming a second continuous conductive layer within the first conductor inner region, the second continuous conductive layer formed on the first conductive end surface and spaced apart from the first continuous conductive layer sidewall to form a first dielectric gap region, the second continuous conductive layer forming a second continuous conductive sidewall extending from a second conductive end surface formed on the first conductive end surface to the first cavity open end, and the second continuous conductive layer formed to define a tubular shaped second conductor inner region encircled by the second continuous conductive layer sidewalls to provide a second dielectric gap region; and
forming a continuous capacitor filler dielectric layer within the first conductor inner region and the second conductor inner region, the capacitor filler dielectric layer covering the first continuous conductive sidewall, the first conductive end surface, the second continuous conductive sidewall, and the second conductive end surface; and
forming a third continuous conductive layer covering the capacitor filler dielectric layer.

2. The method of claim 1, further comprising:
performing a patterned metallization process to operatively connect the first continuous conductive layer and the second continuous conductive layer to a first metallization line or contact; and
performing a patterned metallization process to operatively connect the third continuous conductive layer to a second metallization line or contact.

3. The method of claim 1, further comprising:
depositing a filler dielectric material in a third conductor inner region formed by the third continuous conductive layer covering the continuous capacitor filler dielectric layer.

4. The method of claim 1, wherein the tubular shaped first conductor inner region and the tubular shaped second conductor inner region are cylindrically shaped.

5. The method of claim 1, further comprising:
forming a second cavity in the dielectric substrate region, the second cavity including a closed end surface, an open end opposite to the closed end surface, and a continuous sidewall extending from the closed end surface to the open end through the dielectric substrate region to form an opening of the open end encircled by the continuous sidewall;
forming a first continuous conductive layer on the bottom surface and the continuous sidewall of the second cavity, the first continuous conductive layer forming a first continuous conductive sidewall extending from a first conductive end surface proximate to the second cavity closed end surface, the first continuous conductive sidewall and the first conductive end surface formed to cover the second cavity continuous sidewall and the second cavity end surface, and the first continuous conductive layer formed to define a tubular shaped first conductor inner region encircled by the first continuous conductive layer sidewalls;
forming a second continuous conductive layer within the first conductor inner region, the second continuous conductive layer formed on the first conductive end surface and spaced apart from the first continuous conductive layer sidewall to form a first dielectric gap region, the second continuous conductive layer forming a second continuous conductive sidewall extending from a second conductive end surface formed on the first conductive end surface to the second cavity open end, and the second continuous conductive layer formed to define a tubular shaped second conductor inner region encircled by the second continuous conductive layer sidewalls to provide a second dielectric gap region;
forming a continuous capacitor filler dielectric layer within the first conductor inner region and second conductor inner region, the capacitor filler dielectric layer covering the first continuous conductive sidewall, the first conductive end surface, the second continuous conductive sidewall, and the second conductive end surface; and
forming a third continuous conductive layer covering the continuous capacitor filler dielectric layer,
wherein the first cavity first continuous conductive layer and the second cavity first continuous conductive layer are formed to provide an electrical conduction path from the first continuous conductive layer to the second cavity first continuous conductive layer, and the first cavity third continuous conductive layer and the second cavity third continuous conductive layer are formed to provide an electrical conduction path from the third continuous conductive layer to the second cavity third continuous conductive layer.

6. The method of claim 5, further comprising:
performing a patterned metallization process to operatively connect the first cavity first continuous conductive layer, the first cavity second continuous conductive layer, the second cavity first continuous conductive layer, and the second cavity second continuous conductive layer to a first metallization line or contact; and
performing a patterned metallization process to operatively connect the first cavity third continuous conductive layer and the second cavity third continuous conductive layer to a second metallization line or contact.

7. The method of claim 1, further comprising:
forming a protective dielectric layer covering the third continuous conductive layer.

8. The method of claim 1, further comprising:
etching a via of an incomplete semiconductor structure to enlarge the via and form the first cavity, the via of the incomplete semiconductor structure extending through the dielectric substrate region formed on the substrate.

9. The method of claim 1, further comprising:
forming an oxide layer on the first continuous conductive layer prior to forming the second continuous conductive layer;
forming the second continuous conductive layer within the first conductor inner region; and
prior to forming the continuous capacitor filler dielectric layer within the first conductor inner region and second conductor inner region, removing the oxide layer.

10. A semiconductor capacitor structure comprising:
a dielectric substrate region;
a first cavity formed in the dielectric substrate region, the first cavity including a closed end surface, an open end opposite to the closed end surface, and a continuous sidewall extending from the closed end surface to the open end through the dielectric substrate region to form an opening of the open end encircled by the continuous sidewall;
a first continuous conductive layer formed on the bottom surface and the continuous sidewall of the first cavity, the first continuous conductive layer including a first continuous conductive sidewall extending from a first conductive end surface proximate to the first cavity closed end surface, the first continuous conductive sidewall and the first conductive end surface covering the first cavity continuous sidewall and the first cavity end surface, and the first continuous conductive layer defining a tubular shaped first conductor inner region encircled by the first continuous conductive layer sidewalls;
a second continuous conductive layer formed within the first conductor inner region, the second continuous conductive layer including a first conductive end surface on the first conductive end surface and spaced apart from the first continuous conductive layer sidewall to form a first dielectric gap region, the second continuous conductive layer including a second continuous conductive sidewall extending from a second conductive end surface formed on the first conductive end surface to the first cavity open end, and the second continuous conductive layer defining a tubular shaped second conductor inner region encircled by the second continuous conductive layer sidewalls to provide a second dielectric gap region; and
a continuous capacitor filler dielectric layer within the first conductor inner region and second conductor inner region, the continuous conformal dielectric layer covering the first continuous conductive sidewall, the first conductive end surface, the second continuous conductive sidewall, and the second conductive end surface; and
a third continuous conductive layer covering the continuous capacitor filler dielectric layer.

11. The structure of claim 10, further comprising:
a patterned first metal line or contact operatively connected to the first continuous conductive layer and the second continuous conductive layer; and
a patterned second metal line or contact operatively connected to the third continuous conductive layer.

12. The structure of claim 10, further comprising:
a filler dielectric material formed in a third conductor inner region defined by the third continuous conductive layer covering the continuous capacitor filler dielectric layer.

13. The structure of claim 10, wherein the tubular shaped first conductor inner region and the tubular shaped second conductor inner region are cylindrically shaped.

14. The structure of claim 10, further comprising:
a second cavity formed in the dielectric substrate region, the second cavity including a closed end surface, an open end opposite to the closed end surface, a continuous sidewall extending from the closed end surface to the open end through the dielectric substrate region to form an opening of the open end encircled by the continuous sidewall;
a first continuous conductive layer formed on the bottom surface and the continuous sidewall of the second cavity, the first continuous conductive layer including a first continuous conductive sidewall extending from a first conductive end surface proximate to the second cavity closed end surface, the first continuous conductive sidewall and the first conductive end surface covering the second cavity continuous sidewall and the second cavity end surface, and the first continuous conductive layer defining a tubular shaped first conductor inner region encircled by the first continuous conductive layer sidewalls;
a second continuous conductive layer formed within the first conductor inner region, the second continuous conductive layer including a first conductive end surface on the first conductive end surface and spaced apart from the first continuous conductive layer sidewall to form a first dielectric gap region, the second continuous conductive layer including a second continuous conductive sidewall extending from a second conductive end surface formed on the first conductive end surface to the second cavity open end, and the second continuous conductive layer defining a tubular shaped second conductor inner region encircled by the second continuous conductive layer sidewalls to provide a second dielectric gap region; and
a continuous capacitor filler dielectric layer within the first conductor inner region and second conductor inner region, the continuous conformal dielectric layer covering the first continuous conductive sidewall, the first conductive end surface, the second continuous conductive sidewall, and the second conductive end surface; and
a third continuous conductive layer covering the continuous capacitor filler dielectric layer.

15. The structure of claim 14, wherein the first cavity first continuous conductive layer and the second cavity first continuous conductive layer are operatively connected to provide an electrical conduction path from the first continuous conductive layer to the second cavity first continuous conductive layer, and the first cavity third continuous conductive layer and the second cavity third continuous conductive layer are operatively connected to provide an electrical conduction path from the third continuous conductive layer to the second cavity third continuous conductive layer.

16. The structure of claim 14, further comprising:
a patterned metal line or contact operatively connected to the first cavity first continuous conductive layer, the first cavity second continuous conductive layer, the second cavity first continuous conductive layer, and the second cavity second continuous conductive layer; and
a patterned metal line or contact operatively connected to the first cavity third continuous conductive layer and the second cavity third continuous conductive layer.

17. The structure of claim 10, further comprising:
a protective dielectric layer covering the third continuous conductive layer.

18. A method of forming a capacitor structure in an integrated circuit (IC), the method comprising:
forming a cavity in an intermetal dielectric region, the cavity including a closed end surface, an open end opposite to the closed end surface, and a continuous sidewall extending from the closed end surface to the open end through the intermetal dielectric region to form an opening of the open end encircled by the continuous sidewall;
forming an outer continuous conductive layer on the bottom surface and the continuous sidewall of the cavity, the outer continuous conductive layer forming an outer continuous conductive sidewall extending from an outer conductive layer end surface to the cavity open end, the outer continuous conductive sidewall and the outer conductive end surface formed to cover the cavity continuous sidewall and the cavity end surface, and the outer continuous conductive layer formed to define a cylindrically shaped outer conductor inner region encircled by the outer continuous conductive layer sidewalls;
forming an inner continuous conductive layer within the outer conductor inner region, the inner continuous conductive layer formed on the outer conductive end surface and spaced apart from the outer continuous conductive layer sidewall to form a first dielectric gap region, the inner continuous conductive layer forming an inner continuous conductive sidewall extending from an inner conductive end surface formed on the outer conductive end surface to the cavity open end, and the inner continuous conductive layer formed to define a cylindrical shaped inner conductor inner region encircled by the inner continuous conductive layer sidewalls to provide a second dielectric gap region;
forming a continuous capacitor filler dielectric layer within the first dielectric gap region and the second dielectric gap region; and
forming an electrode conductive layer covering the capacitor filler dielectric layer.

19. The method of claim 18, further comprising:
etching a via of an incomplete semiconductor structure to enlarge the via and form the cavity, the via of the incomplete semiconductor structure extending through the intermetal dielectric region.

20. The method of claim 19, further comprising:
forming an oxide layer on the outer continuous conductive layer prior to forming the inner continuous conductive layer;
forming the inner continuous conductive layer within the outer conductor inner region; and
prior to forming the continuous capacitor filler dielectric layer within the outer conductor inner region and inner conductor inner region, removing the oxide layer.
